(19) United States
(12) Patent Application Publication
(10) Pub. No.: US 2008/0153178 A1
(43) Pub. Date: Jun. 26, 2008

(54) Method for Fabricating MRAM

(76) Inventor: HYO SANG KIM, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/860,133

(22) Filed: Sep. 24, 2007

(30) Foreign Application Priority Data
Dec. 26, 2006 (KR) 10-2006-0134064

(51) Int. Cl. H01L 21/00

(52) U.S. Cl. 438/3; 257/E21.001

(57) ABSTRACT

A method of fabricating a magnetic random access memory (MRAM) is provided. A metal interconnection, a magnetic tunnel junction layer, and an interlayer dielectric layer are formed on a semiconductor substrate. A portion of the interlayer dielectric layer is selectively removed, leaving protruded regions. A metal layer is then formed on the interlayer dielectric layer and planarized using the protruded portions of the interlayer dielectric layer as a target.

### CROSS-REFERENCE TO RELATED APPLICATION

The present application claims the benefit under 35 U.S.C. §119 of Korean Patent Application No. 10-2006-0134064, filed Dec. 26, 2006, which is hereby incorporated by reference in its entirety.

### BACKGROUND

A Magnetic Random Access Memory (MRAM) is a nonvolatile memory device, such as a flash memory device, which uses the characteristics of a magnetic member to store data.

FIG. 1 is a cross-sectional view of a typical related art MRAM cell, and FIG. 2 is a top view of a wafer and a portion of a wafer including related art MRAM cells.

In general, when manufacturing MRAM cells, as shown in FIG. 1, transistors 20 are formed on a semiconductor substrate 10 and multi-layered metal interconnections 30 are connected to the transistors 20. Multi-layered interlayer dielectric layers 40 are interposed between the metal interconnections 30, digit lines 50 are formed on the final interlayer dielectric layer 40, and magnetic tunnel layers 60 are formed on the digit lines 50. Lastly, a titanium nitride (TiN) layer 70 is formed on the entire surface of the semiconductor substrate 10 including the magnetic tunnel layers 60.

The TiN layer 70 typically has a thickness of from about 400 Å to about 500 Å and a roughness equal to or less than about 5 Å.

The TiN layer 70 is often initially formed much thicker and with a roughness of about 50 Å. Then, a chemical mechanical polishing (CMP) process is performed on the TiN layer 70 to give a roughness of about 5 Å or less.

However, due to the limitations of precision in CMP equipment, a thin metal layer having a thickness of about 400 Å cannot be uniformly formed on the entire surface of the wafer. Referring to FIG. 2, the TiN layer 70 typically remains at the center portion (dotted circle) of the wafer, but is not present at the wafer edge region. This leads to the wafer having poor uniformity, partly due to over-polish. Thus, the yield rate is reduced at the wafer edge region. Also, the non-uniformity of the TiN layer 70 may cause some chips to have different characteristics depending on their positions on the wafer.

Table 1 shows the thickness of the TiN layer (Å) of four wafers according to the measurement positions X and Y shown in FIG. 2.

TABLE 1
TiN layer thickness as a function of wafer position

| position | wafer 1 | wafer 2 | wafer 3 | wafer 4 | X | Y |
|---|---|---|---|---|---|---|
| 1 | 525 | 404 | 458 | 452 | 5.082 | 65.536 |
| 2 | 520 | 449 | 478 | 456 | 5.065 | 45.237 |
| 3 | 442 | 447 | 472 | 445 | 5.048 | 24.939 |
| 4 | 507 | 455 | 494 | 481 | 5.031 | 4.641 |
| 5 | 503 | 479 | 484 | 460 | 5.013 | −15.658 |
| 6 | 519 | 435 | 477 | 470 | 4.996 | −35.956 |
| 7 | 505 | 427 | 475 | 454 | 4.979 | −56.255 |
| 8 | Not measured | | | | 4.962 | −76.553 |
| 9 | Not measured | | | | −76.569 | 4.71 |
| 10 | 515 | 430 | 468 | 472 | −56.169 | 4.692 |
| 11 | 507 | 446 | 457 | 448 | −35.769 | 4.675 |
| 12 | 506 | 444 | 480 | 440 | −15.369 | 4.658 |
| 13 | 480 | 422 | 484 | 452 | 25.431 | 4.623 |
| 14 | 495 | 441 | 497 | 481 | 45.831 | 4.606 |
| 15 | 500 | 386 | 457 | 465 | 66.231 | 4.589 |

| | | | |
|---|---|---|---|
| 16 | Not measured | 86.631 | 4.572 |

| | | | | |
|---|---|---|---|---|
| Average | 502 | 436 | 475 | 460 |

Table 1 shows that the TiN layer is not present at the edge region of the wafer since the thickness of the TiN layer cannot be measured at that region.

The method for fabricating the MRAM according to the related art represents problems as follows.

In existing MRAM devices, the TiN layer is not present at the edge region of a wafer having a plurality of the MRAM devices since over-polish occurs at the wafer edge region during the CMP process on the TiN layer. This leads to reduced yield rate and uniformity at the wafer edge region. Additionally, some chips may have different characteristics depending on the positions on the wafer.

Thus, there exists a need in the art for an improved method of forming a metal layer on an MRAM device.

### BRIEF SUMMARY

Embodiments of the present invention provide a method of fabricating an MRAM cell, in which a metal layer is substantially uniformly polished during a chemical mechanical polishing (CMP) process.

A method of fabricating magnetic random access memory (MRAM) includes: forming a metal interconnection on a semiconductor substrate; forming a magnetic tunnel junction layer on the metal interconnection; forming an interlayer dielectric layer on the semiconductor substrate; planarizing the interlayer dielectric layer such that the magnetic tunnel junction layer is exposed; selectively removing a portion of the interlayer dielectric layer; forming a metal layer on the interlayer dielectric layer; and performing a planarization process on the metal layer using protruded portions of the interlayer dielectric layer as a target.

### BRIEF DESCRIPTION OF THE DRAWINGS

FIG. 1 is a cross-sectional view showing a related art MRAM device.

FIG. 2 is a top view of a wafer and a portion of a wafer for a related art MRAM.

FIGS. 3 to 6 are cross-sectional views showing a method of fabricating an MRAM device according to an embodiment of the present invention.

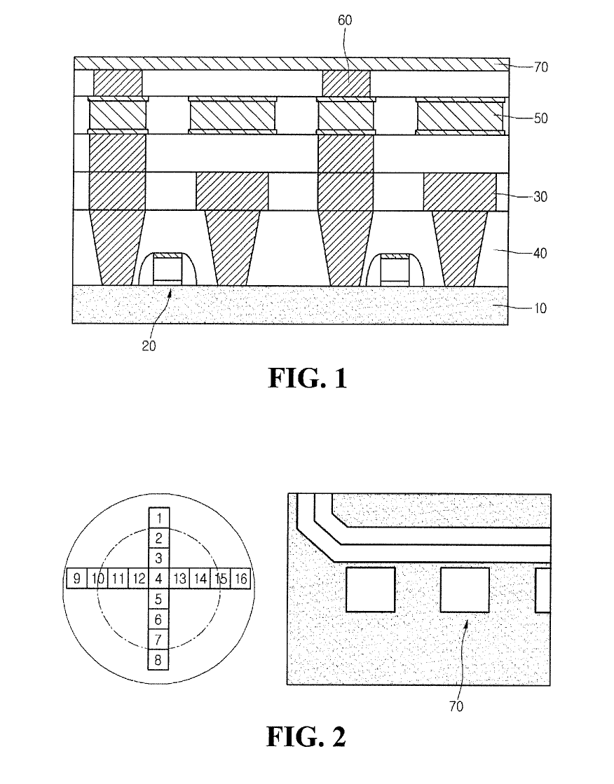

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

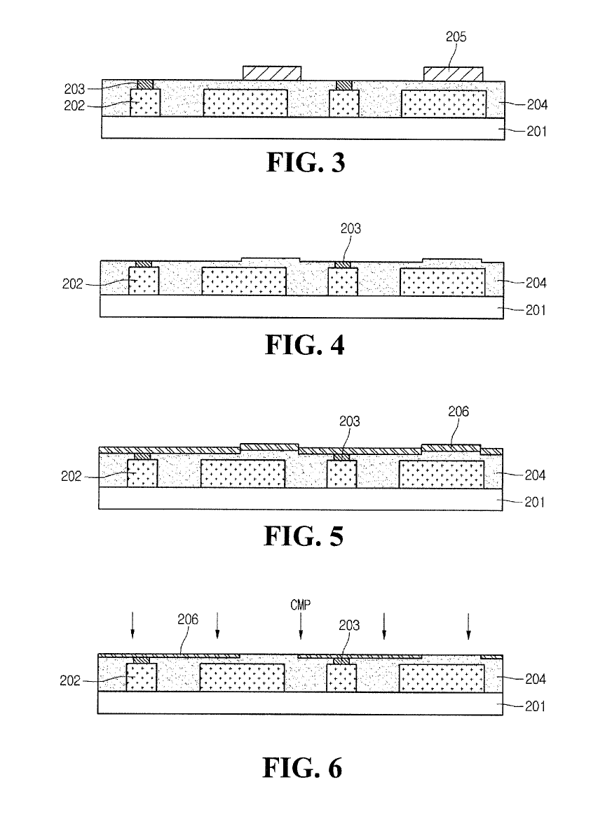

FIGS. 3 to 6 are cross-sectional views showing a method of fabricating an MRAM device according to an embodiment of the present invention.

Referring to FIG. 3, a first metal layer can be deposited on a semiconductor substrate 201 having transistors (not shown). Then, the first metal layer can be selectively removed, thereby forming metal interconnections 202. In an embodiment, the first metal layer can be selectively removed through a photo process and etching process.

A magnetic tunnel junction layer 203 can be selectively formed on the metal interconnections 202. Then, an interlayer dielectric layer 204 can be formed on the semiconductor substrate 201 including the magnetic tunnel junction layer 203.

Next, a chemical mechanical polishing (CMP) process can be performed on the entire surface of the interlayer dielectric layer 204 until the upper surface of the magnetic tunnel junction layer 203 is exposed.

Then, a photoresist can be coated on the interlayer dielectric layer 204 and selectively patterned to form a photoresist pattern 205. In an embodiment, the photoresist can be patterned through an exposure and developing process.

Referring to FIG. 4, a portion of the exposed upper surface of the interlayer dielectric layer 204 can be removed. In an embodiment, the exposed interlayer dielectric layer 204 is reduced by a thickness of about 500 Å. In many embodiments, the portion of the interlayer dielectric layer is removed through a dry etching process using the photoresist pattern 205 as an etching mask.

In many embodiments, since the portions of the interlayer dielectric layer 204 under the photoresist pattern 205 are only thicker than the rest of the interlayer dielectric layer 204 by about 500 Å, the extra thickness has little effect on the insulation of the metal interconnections.

Then, the photoresist pattern 205 can be removed.

Referring to FIG. 5, a second metal layer 206 can be deposited on the entire surface of the interlayer dielectric layer 204. For example, the second metal layer can be a titanium nitride (TiN) layer. In an embodiment, the deposition thickness of the second metal layer 206 is from about 1000 Å to about 2000 Å. In one embodiment, the deposition thickness of the second metal layer 206 is about 1500 Å.

Since the portions of the interlayer dielectric layer 204 that were below the photoresist pattern 205 were not etched, those portions may be thicker than and protrude above the rest of the interlayer dielectric layer 204. Accordingly, the second metal layer 206 protrudes on the substrate 201 where the interlayer dielectric layer 204 protrudes.

Referring to FIG. 6, a CMP process can be performed on the entire surface of the second metal layer 206 using the protruded portions of the upper surface of the interlayer dielectric layer 204 as a target. In an embodiment, the second metal layer 206 can have about 1000 Å polished away through the CMP process, such that a second metal layer 206 that was deposited with a thickness of about 1500 Å would have a thickness of about 500 Å after the CMP process.

As stated above, in an embodiment, the second metal layer can be a TiN layer. Due to the characteristics of metal slurry that can be used in the CMP process, the selectivity between TiN and the interlayer dielectric layer 204 can be about 50:1. Thus, a TiN layer can be uniformly over the whole area of the wafer, even if the wafer is over-polished.

Embodiments of the present invention provide portions of the interlayer dielectric layer 204 that protrude from the top surface of the interlayer dielectric layer, thereby allowing the second metal layer to be uniformly formed over the whole area of a wafer. The second metal layer, such as a TiN layer, can be uniformly formed even if a CMP process is performed after the second metal layer has been deposited.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a magnetic random access memory (MRAM), comprising:
forming a metal interconnection on a semiconductor substrate;
forming a magnetic tunnel junction layer on the metal interconnection;
forming an interlayer dielectric layer on the semiconductor substrate including the metal interconnection and magnetic tunnel junction layer;
planarizing the interlayer dielectric layer such that a top surface of the magnetic tunnel junction layer is exposed;
removing a portion of the interlayer dielectric layer, resulting in at least one protruded portion of the interlayer dielectric layer;
forming a metal layer on the interlayer dielectric layer having the at least one protruded portion; and
planarizing the metal layer using the at least one protruded portion of the interlayer dielectric layer as a target.

2. The method according to claim 1, wherein removing a portion of the interlayer dielectric layer comprises:
depositing a photoresist on the interlayer dielectric layer;
patterning the photoresist through an exposure and developing process to form a photoresist pattern;
performing a dry etching process on the interlayer dielectric layer using the photoresist pattern as an etching mask; and
removing the photoresist pattern.

3. The method according to claim 1, wherein planarizing the interlayer dielectric layer comprises performing a chemical mechanical polishing (CMP) process.

4. The method according to claim 1, wherein planarizing the metal layer comprises performing a CMP process.

5. The method according to claim 1, wherein the metal layer comprises titanium nitride (TiN).

6. The method according to claim 1, wherein the forming a metal layer comprises depositing the metal layer to a thickness of from about 1000 Å to about 2000 Å.

7. The method according to claim 6, wherein the forming a metal layer comprises depositing the metal layer to a thickness of about 1500 Å.

8. The method according to claim 1, wherein the at least one protruded portion of the interlayer dielectric layer protrudes to about 500 Å above a non-protruded portion of the interlayer dielectric layer.

9. The method according to claim 1, wherein after the metal layer is planarized, the metal layer has a thickness of about 500 Å.
